(19) United States
(12) Patent Application Publication
(10) Pub. No.: US 2014/0134836 A1
(43) Pub. Date: May 15, 2014

(54) DIELECTRIC CAP LAYER FOR REPLACEMENT GATE WITH SELF-ALIGNED CONTACT

(71) Applicants: INTERNATIONAL BUSINESS MACHINES CORPORATION, Armonk, NY (US); GLOBALFOUNDRIES, INC., Grand Cayman, KY (US)

(72) Inventors: BALASUBRAMANIAN PRANATHARTHIHARAN, WATERVLIET, NY (US); CHARAN VEERA VENKATA SATYA SURISETTY, CLIFTON PARK, NJ (US); JUNLI WANG, SLINGERLANDS, NY (US); CHANG SEO PARK, IRVINE, CA (US); RUILONG XIE, SCHENECTADAY, NY (US)

(73) Assignees: GLOBALFOUNDRIES, INC., GRAND CAYMAN (KY); INTERNATIONAL BUSINESS MACHINES CORPORATION, ARMONK, NY (US)

(21) Appl. No.: 13/672,864

(22) Filed: Nov. 9, 2012

(51) Int. Cl. H01L 21/283

(52) U.S. Cl. 438/586; 257/E21.19

(57) ABSTRACT

Embodiments of the present invention provide a method of forming borderless contact for transistors. The method includes forming a sacrificial gate structure embedded in a first dielectric layer, the sacrificial gate structure including a sacrificial gate and a second dielectric layer surrounding a top and sidewalls of the sacrificial gate; removing a portion of the second dielectric layer that is above a top level of the sacrificial gate to create a first opening surrounded directly by the first dielectric layer; removing the sacrificial gate exposed by the removing of the portion of the second dielectric layer to create a second opening surrounded by a remaining portion of the second dielectric layer; filling the second opening with one or more conductive materials to form a gate of a transistor; and filling the first opening with a layer of dielectric material to form a dielectric cap of the gate of the transistor.

### FIELD OF THE INVENTION

The present invention relates generally to the field of semiconductor device manufacturing. In particular it relates to method, and structure formed thereby, of forming dielectric cap over replacement gate of transistor to facilitate manufacturing of self-aligned contact.

### BACKGROUND

Continuous scaling in manufacturing of complementary-metal-oxide-semiconductor (CMOS) transistors has lead to recent development of borderless contact, also known as self-aligned contact (SAC), for source and drain of a transistor. This is because the manufacturing process of conventional source/drain (S/D) contact is known for frequently creating issues such as causing short between a gate and a S/D region of a transistor, wherein such short may sometimes be detrimental to the performance of the transistor when a pitch between the transistor and a neighboring transistor is extremely narrow or short under highly scaled situation. On the other hand, borderless contact (or SAC) generally does not possess this problem of causing S/D to get connected to or contact the gate, and so the manufacturing process has much greater process window.

In order to manufacture or form borderless contact (or SAC) within current replacement metal gate (RMG) integration scheme, several methods have been developed. One of the methods includes forming a dielectric cap layer on top of the gate to isolate the gate from the S/D contact which prevents potential shorting between the gate and the S/D contact. For example, one of the straightforward methods may include steps of recessing the metal gate of a RMG structure, including work-function (WF) metals and gap filling metals such as aluminum (Al) and/or tungsten (W); depositing dielectric material in and on top of the recessed area of the RMG structure; and polishing the deposited dielectric material, through for example a chemical-mechanic-polishing (CMP) process, to remove any excess amount of the dielectric material and form the dielectric cap layer in the gate area. Hereinafter, the dielectric cap layer on top of the gate may from time to time be referred to as a dielectric cap as well.

Although some initial success has been reported with regard to the process described above in forming dielectric cap layer for SAC, there are still a few challenges remaining that may potentially limit possible wide application of this process. For example, in order to form the dielectric cap, additional gate height is needed in order to count or compensate for the height losses due to the CMP process, but such additional gate height makes RMG metal fill extremely difficult due to increased aspect ratio. Other challenges may include, for example, the need to make the un-landed metal recess controllable. Moreover, adaptability of this process to further scaling in future is also challenging and untested. For example, even though it may have been found working for 14 nm generation technology with a gate length Lg of approximate 20 nm, the process is unlikely to be easily transferrable to next generation or generations such as, for example, the 10 nm generation with a gate length of approximate 15 nm, which will obviously have an even higher aspect ratio than the current generation of 20 nm gate length.

### BRIEF SUMMARY OF EMBODIMENTS

Embodiments of the present invention provide a method of forming dielectric cap on a gate of transistor for borderless contact formation of the transistor. The method includes forming a sacrificial gate structure embedded in a first dielectric layer, with the sacrificial gate structure having a sacrificial gate, on top of a channel region of a transistor, and a second dielectric layer surrounding a top and sidewalls of the sacrificial gate; removing a portion of the second dielectric layer that is above a top level of the sacrificial gate to create a first opening surrounded directly by the first dielectric layer; removing the sacrificial gate exposed by the removing of the portion of the second dielectric layer to create a second opening surrounded by a remaining portion of the second dielectric layer, with the second opening having a narrower width than that of the first opening; filling the second opening with one or more conductive materials to form a gate of the transistor; and filling the first opening with a layer of dielectric material to form a dielectric cap of the gate of the transistor.

In one embodiment, the method further includes creating a third opening in the first dielectric layer, the third opening being self-aligned to the dielectric cap and the remaining portion of the second dielectric layer underneath the dielectric cap surrounding the gate of the transistor; and filling the third opening with a conductive material to form a contact to a source/drain of the transistor.

According to one embodiment, creating the third opening includes applying a selective etching process to etch the first dielectric layer, with the etching process being selective to the dielectric cap and the remaining portion of the second dielectric layer underneath thereof.

In one embodiment, the dielectric cap and the second dielectric layer are of nitride material and the first dielectric layer is of oxide material.

In another embodiment, the first dielectric layer includes a lower portion of flowable oxide and an upper portion of high density plasma deposited oxide.

According to another embodiment, forming the sacrificial gate structure includes forming a hard mask on top of a layer of dummy gate material; etching the layer of dummy gate material to form the dummy gate using the hard mask as a pattern of the dummy gate; forming a set of spacers at sidewalls of the hard mask and sidewalls of the dummy gate; depositing the first dielectric layer surrounding the set of spacers; and applying a chemical-mechanic-polishing (CMP) process to remove a top portion of the hard mask and top portions of the set of spacers.

In one embodiment, the hard mask has an upper portion of oxide material and a lower portion of nitride material, and wherein removing the top portion of the hard mask includes removing the upper portion of the hard mask of oxide material.

In another embodiment, the set of spacers are of nitride material and wherein remaining portions of the set of spacers, together with the lower portion of the hard mask of nitride material, form the second dielectric layer.

In yet another embodiment, the nitride material of the set of spacers is different from the nitride material of the lower portion of the hard mask.

According to yet another embodiment, the one or more conductive materials include a work-function metal and a gap-filling metal of aluminum, and wherein filling the second opening with the one or more conductive materials includes depositing the work-function metal in at least the second opening; depositing the gap-filling metal of aluminum on top of the work-function metal and inside the second opening; and substantially removing the work-function metal and the gap-filling metal of aluminum that are deposited in the first opening through a selective etching process by applying a dielectric liner underneath the work-function metal as an etch-stop layer, wherein the dielectric liner is deposited prior to depositing the work-function metal.

According to another embodiment, the transistor is a fin-type field-effect-transistor and the channel region is in a fin-shape.

### BRIEF DESCRIPTION OF THE DRAWINGS

The present invention will be understood and appreciated more fully from the following detailed description of preferred embodiments, taken in conjunction with the accompanying drawings of which:

FIG. 1 is a demonstrative illustration of a method of forming a dielectric cap layer on a gate for borderless contacts of transistors according to an embodiment of the present invention;

FIG. 2 is a demonstrative illustration of a method of forming a dielectric cap layer on a gate for borderless contacts of transistors, following the step illustrated in FIG. 1, according to an embodiment of the invention;

FIG. 3 is a demonstrative illustration of a method of forming a dielectric cap layer on a gate for borderless contacts of transistors, following the step illustrated in FIG. 2, according to an embodiment of the invention;

FIG. 4 is a demonstrative illustration of a method of forming a dielectric cap layer on a gate for borderless contacts of transistors, following the step illustrated in FIG. 3, according to an embodiment of the invention;

FIG. 5 is a demonstrative illustration of a method of forming a dielectric cap layer on a gate for borderless contacts of transistors, following the step illustrated in FIG. 4, according to an embodiment of the invention;

FIG. 6 is a demonstrative illustration of a method of forming a dielectric cap layer on a gate for borderless contacts of transistors, following the step illustrated in FIG. 5, according to an embodiment of the invention;

FIG. 7 is a demonstrative illustration of a method of forming a dielectric cap layer on a gate for borderless contacts of transistors, following the step illustrated in FIG. 6, according to an embodiment of the invention;

FIG. 8 is a demonstrative illustration of a method of forming a dielectric cap layer on a gate for borderless contacts of transistors, following the step illustrated in FIG. 7, according to an embodiment of the invention;

FIG. 9 is a demonstrative illustration of a method of forming a dielectric cap layer on a gate for borderless contacts of transistors, following the step illustrated in FIG. 8, according to an embodiment of the invention;

FIG. 10 is a demonstrative illustration of a method of forming a dielectric cap layer on a gate for borderless contacts of transistors, following the step illustrated in FIG. 9, according to an embodiment of the invention;

FIG. 11 is a demonstrative illustration of a method of forming a dielectric cap layer on a gate for borderless contacts of transistors, following the step illustrated in FIG. 10, according to an embodiment of the invention;

FIG. 12 is a demonstrative illustration of a method of forming a dielectric cap layer on a gate for borderless contacts of transistors, following the step illustrated in FIG. 11, according to an embodiment of the invention;

FIG. 13 is a demonstrative illustration of a method of forming a dielectric cap layer on a gate for borderless contacts of transistors, following the step illustrated in FIG. 2 and FIG. 3, according to another embodiment of the invention; and

FIG. 14 is a demonstrative illustration of a method of forming a dielectric cap layer on a gate for borderless contacts of transistors, following the step illustrated in FIG. 11 in a situation when the structure illustrated in FIG. 13 is used during the step illustrated in FIG. 4, according to an embodiment of the invention.

It will be appreciated that for the purpose of simplicity and clarity of illustration, elements in the drawings have not necessarily been drawn to scale. For example, dimensions of some of the elements may be exaggerated relative to those of other elements for clarity purpose.

### DETAILED DESCRIPTION OF THE INVENTION

In the following detailed description, numerous specific details are set forth in order to provide a thorough understanding of various embodiments of the invention. However, it is to be understood that embodiments of the invention may be practiced without these specific details.

In the interest of not obscuring presentation of essences and/or embodiments of the invention, in the following detailed description, some processing steps and/or operations that are known in the art may have been combined together for presentation and/or for illustration purpose and in some instances may have not been described in detail. In other instances, some processing steps and/or operations that are known in the art may not be described at all. In addition, some well-known device processing techniques may have not been described in detail and, in some instances, may be referred to other published articles, patents, and/or published patent applications for reference in order not to obscure description of essence and/or embodiments of the invention. It is to be understood that the following descriptions may have rather focused on distinctive features and/or elements of various embodiments of the present invention.

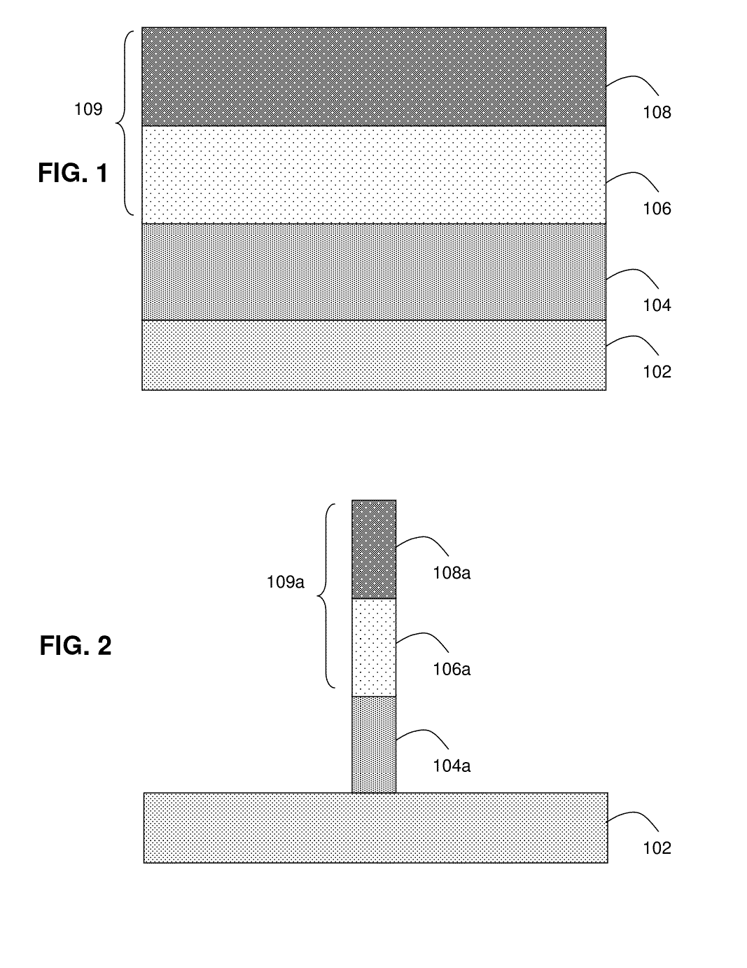

FIG. 1 is a demonstrative illustration of a method of forming a dielectric cap layer on a gate for borderless contacts of transistors according to an embodiment of present invention. For example, the method may start with a semiconductor substrate 102 and includes a step of forming multiple layers, such as layers 104, 106, and 108 on top of substrate 102. More specifically, 102 may be a portion of a semiconductor substrate serving as an active region, such as a channel region, for the transistor being formed and therefore may be referred to as active layer 102 hereinafter. The transistor may be a field-effect-transistor (FET) and may further be a planar transistor, a fin-type transistor, a 3-dimensional (3D) transistor, or any types of transistors that present invention may be suitable for. Nevertheless, for description purpose only hereinafter without losing generality, embodiments of present invention may be described in a context of forming a fin-type field-effect-transistor (fin-FET), and the fin-FET may be made through a replacement gate or replacement metal gate process with self-aligned contacts.

According to one embodiment of present invention, the method includes depositing layer 104 of, for example, poly-silicon material directly on top of active layer 102. As will be described below in more details, during the manufacturing process, layer 104 may be formed or etched into a dummy gate and the dummy gate may further be removed, at some point during one of the process steps as is so designed by the process. Because of this, layer 104 may from time to time be referred to as a dummy gate layer. Additionally, because layer 104 is a dummy gate layer, any suitable materials, in addition to poly-silicon, may be used as well so long as the material does not create process-related issues and enables selective etching relative to other dielectric materials used in the process, as will be described below in more details. Generally, poly-silicon is preferably used for dummy gate.

To transform dummy gate layer 104 into a dummy gate, one embodiment of present invention includes depositing, on top of dummy gate layer 104, a hard mask layer which may be patterned into a pattern of the dummy gate later through a photolithographic process and used in an etching process to transfer the pattern of dummy gate into the underneath dummy gate layer 104. The hard mask layer may be a single layer or a composition of multiple layers of different materials. For example, in one embodiment, the method may include forming a composite hard mask layer 109 having a lower portion 106 of nitride material and an upper portion 108 of oxide material. In other words, a layer 106 of nitride material may first be deposited on top of dummy gate layer 104, and a layer 108 of oxide material may subsequently be deposited on top of nitride layer 106 to form the composite hard mask layer 109.

FIG. 2 is a demonstrative illustration of a method of forming a dielectric cap layer on a gate for borderless contacts of transistors according to an embodiment of present invention, following the step of FIG. 1. More specifically, one embodiment of the present invention may include first transforming composite hard mask layer 109 into a hard mask 109a. The transformation may include forming the lower portion 106 and upper portion 108 of hard mask layer 109 into hard masks 106a and 108a, respectively, through one or more wet or dry etching processes. During the etching processes of hard mask layer 109, a photo-resist mask (not shown) may be applied to protect the top surface area of hard mask 109a. Following the formation of hard mask 109a, the pattern of hard mask 109a may subsequently be transferred to underneath dummy gate layer 104 thereby creating dummy gate 104a. The etching of dummy gate layer 104 may be made by applying the combined hard masks 106a and 108a, and etched through a reactive-ion-etching (RIE) process. The RIE etching process may be a selective etching process and may be designed to stop at active layer 102.

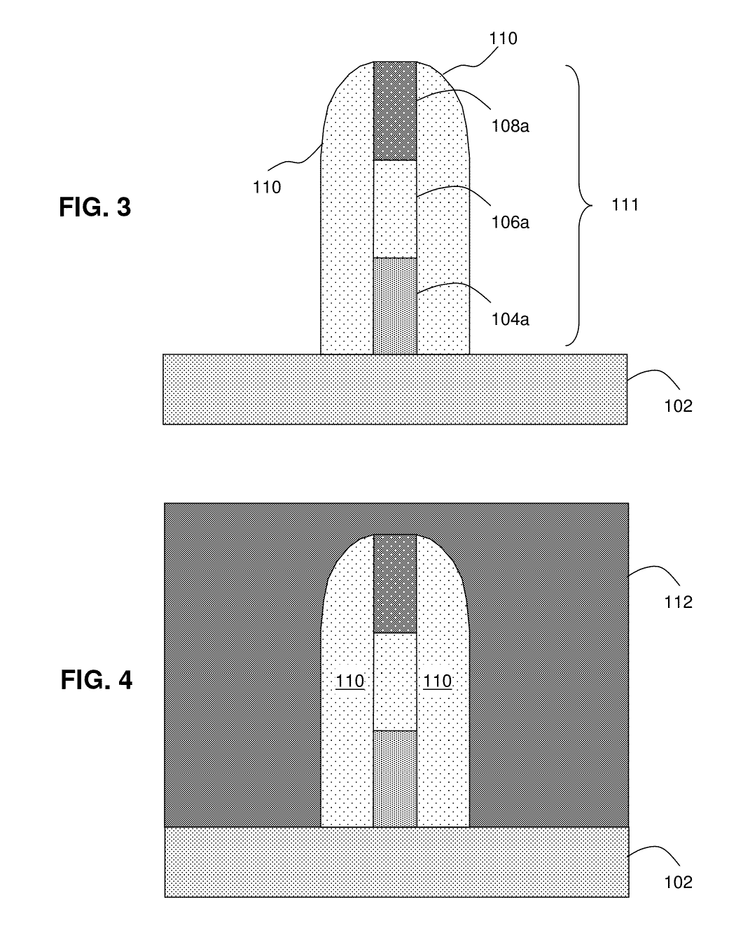

FIG. 3 is a demonstrative illustration of a method of forming a dielectric cap layer on a gate for borderless contacts of transistors according to an embodiment of present invention, following the step of FIG. 2. More specifically, according to one embodiment of present invention, the method may include forming a set of spacers 110 next to sidewalls of dummy gate 104a. Being adjacent to sidewalls of dummy gate 104a, spacers 110 may sometimes be referred to as sidewall spacers as well. In one embodiment, spacers 110 may be formed next to sidewalls of hard masks 106a and 108a as well, having a height higher than that of dummy gate 104a. In forming sidewall spacers 110, a preferably conformal layer of spacer-suitable material, such as dielectric material of nitride or oxide, may first be deposited to cover dummy gate 104a and hard masks 106a and 108a on top thereof. In the below description, the conformal layer is assumed to be nitride material for purpose of description without losing generality of the present invention although other material may be used as well. The conformal layer is then subjected to a directional etching process such as a RIE etching process, vertically, which removes most portion thereof and leaving only portions 110 that are adjacent to sidewalls of dummy gate 104a and hard masks 106a and 108a on top thereof. Dummy gate 104a, hard masks 106a and 108a (collectively hard mask 109a), and the set of sidewall spacers 110 together form an initial dummy gate structure 111, as being demonstratively illustrated in FIG. 3.

FIG. 4 is a demonstrative illustration of a method of forming a dielectric cap layer on a gate for borderless contacts of transistors according to an embodiment of present invention, following the step of FIG. 3. More specifically, one embodiment of present invention includes depositing an inter-layer dielectric (ILD) layer 112 on top of active layer 102 as well as covering the entire initial dummy gate structure 111. In FIG. 4, for illustrative purpose, only one initial dummy gate structure 111 is illustrated for demonstrative purpose. However, in reality a plurality of similar dummy gate structures may be formed on top of substrate/active layer 102, and thus ILD layer 112 may fill gaps between these dummy gate structures. As part of a replacement gate process, ILD layer 112 is generally formed as a preparation step of opening dummy gate 104a, as being described below in more details.

In order for ILD layer 112 to properly and substantially fill gaps between neighboring dummy gate structures 111, in particular when such gaps are highly scaled to be relatively narrow, flowable oxide (F-OX) may preferably be used as the dielectric material of ILD layer 112 to more effectively fill the gaps. But on the other hand, flowable oxide is generally known of performing poorly during a chemical-mechanic-polishing (CMP) process. The poor performance may be reflected in, for example, dishing effect of polished surface. In addition, flowable oxide has poor etch resistance against HF, as both CMP process and etching with HF as etchant are common in current replacement gate process.

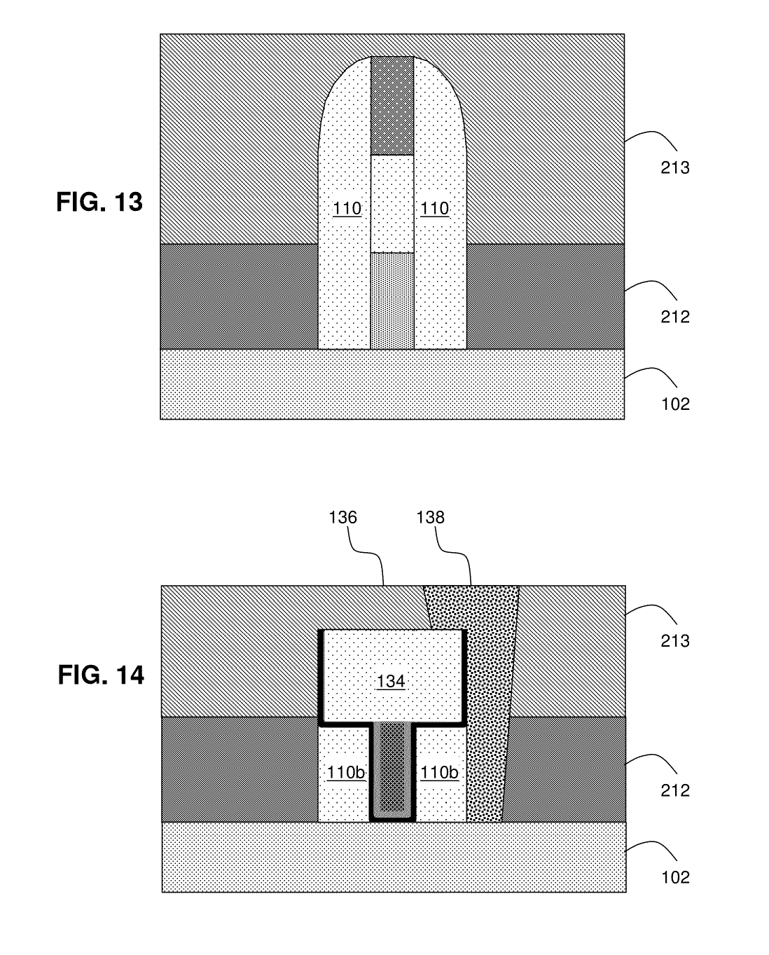

In view of the above and according to one embodiment of present invention, a composite ILD layer made partially of flowable oxide may be used to fill gaps between neighboring dummy gate structures on top of active layer 102, as a mean to mitigate the potential concerns described above. Reference is now made to FIG. 13 which may be a step following the steps illustrated in FIG. 2 and FIG. 3. To form the composite ILD layer, an ILD layer 112 of flowable oxide (F-OX) may be initially formed. The formed ILD layer 112 may then be recessed to a level that is lower than the initial dummy gate structure 111. For example, the level of ILD layer 112 may be made lower than, for example, that of upper portion of hard mask 109a (i.e., hard mask 108a). More specifically, in one embodiment, height of ILD layer 112 may be lowered through a selective etching process to be substantially close to the top surface of dummy gate 104a, as being demonstratively illustrated in FIG. 13 as ILD layer 212.

In the recesses so created on top of the lowered ILD layer 212, between neighboring dummy gate structures, alternative materials such as oxide, which may be formed through high density plasma (HDP), may be used to fill the recesses thereby forming a second ILD layer 213 that covers the dummy gate structures, as being demonstratively illustrated in FIG. 13. Oxide formed through HDP will be able to provide better CMP performance as well as better etch selectivity, when being compared with the underneath flowable oxide layer 212.

Reference is now made back to FIG. 4. In the following, for description purpose only, it is assumed that ILD layer 112 is made of a single kind of material and is used to cover, and fill the gaps between, dummy gate structures. A person skilled in the art will appreciate that description similar to the below may equally be applied for a process that employs multiple ILD layers, such as ILD layers 212 and 213 as being illustrated in FIG. 13, in forming a dielectric cap or dielectric cap layer on a gate for borderless contacts of transistors.

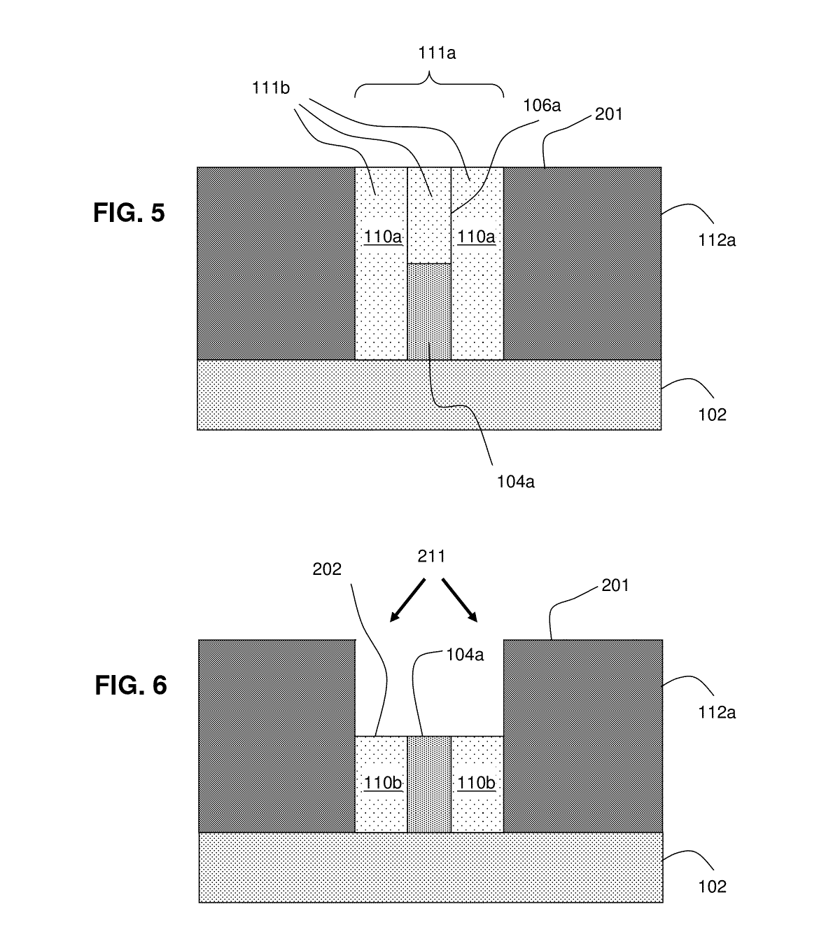

FIG. 5 is a demonstrative illustration of a method of forming a dielectric cap layer on a gate for borderless contacts of transistors according to an embodiment of present invention, following the step of FIG. 4. More specifically, one embodiment of the invention includes applying a CMP process to remove at least some of the hard masks 106a and 108a as part of a process of opening up dummy gate 104a. For example, in FIG. 5, it is illustrated that the upper portion of hard mask 109a (oxide hard mask 108a) may be removed through CMP polishing to expose the underneath lower portion of hard mask 109a (nitride hard mask 106a). The removal of hard mask 108a also removes a top portion of sidewall spacers 110 to create a set of new sidewall spacers 110a with reduced height, and remove a portion of ILD layer 112 which becomes ILD layer 112a. The CMP process applies strategically difference in etch resistance between upper portion and lower portion of hard mask 109a, that is, between hard mask 108a and hard mask 106a which are oxide and nitride respectively, to use hard mask 106a as an etch stop. Hard mask 106a, new sidewall spacers 110a, and ILD layer 112a have a coplanar top surface 201. The CMP process removes upper portion 108a of hard mask 109a, creating a dummy gate structure 111a that includes dummy gate 104a, hard mask 106a, and new sidewall spacers 110a.

So far, embodiment of the present invention has provided a method of forming dummy gate structure 111a embedded in a dielectric layer 112a (e.g., a first dielectric layer). Dummy gate structure 111a includes dummy gate 104a and another dielectric layer (e.g., a second dielectric layer) consisting of hard mask 106a and sidewall spacers 110a and being collectively referred to as dielectric layer 111b, covering the top and sidewalls of dummy gate 104a. The first and second dielectric layers 112a and 111b may be different in their dielectric material such as one being oxide and another being nitride to enable selective etching in follow-up process steps through their difference in etch selectivity. The dummy gate structure 111a is formed on top of active layer 102 which may be a channel region of a transistor including a planar FET, a fin-FET, a 3D-FET and any other suitable transistors.

It is to be noted that dummy gate structure 111a includes dielectric layer 111b over dummy gate 104a, wherein a top portion of dielectric layer 111b that is above the top level of dummy gate 104a has a width wider than that of dummy gate 104a. For example, a width of dummy gate structure 111a at a top thereof may be substantially same as a width of dummy gate structure 111a at a bottom thereof. In one embodiment, widths at the top and bottom of dummy gate structure 111a may be within 10% and preferably within 5% in difference. In other words, dummy gate structure 111a has a structure such that removing the upper portion of dielectric layer 111b that is above the level of dummy gate 104a may create an opening that is wider than the width of dummy gate 104a. Moreover, the width of dummy gate 104a may be less than 35%-65% of total width of dummy gate structure 111a, comparing with prior art of close to 80-90%. According to one embodiment of present invention, the opening created by removing the upper portion of dielectric layer 111b that is above the level of dummy gate 104a will be much less affected by the continued trend of scaling in gate width, comparing to currently existing technology, because the total width of the opening is much less dependent upon the width of the gate length.

So far, embodiments of present invention have provided a method of forming the distinctive dummy gate structure 111a illustrated in FIG. 5 with properties being described above. However, embodiments of present invention are not limited to the above method, and any other methods that may form a similar dummy gate structure to with properties similar to the above 111a are all contemplated to be within the spirit of scope of present invention. For example, another method of forming a similar dummy gate structure may include forming a dummy gate first, forming a conformal dielectric layer next to cover the dummy gate, and then removing portions of the conformal dielectric layer that are not adjacent to the dummy gate by applying a specially designed hard mask that covers only the top portion of the conformal dielectric layer that is above the dummy gate level.

FIG. 6 is a demonstrative illustration of a method of forming a dielectric cap layer on a gate for borderless contacts of transistors according to an embodiment of present invention, following the step of FIG. 5. More specifically during this process, nitride hard mask 106a together with a top portion of nitride sidewall spacers 110a (collectively dielectric layer 111b) may be selectively removed by applying a suitable wet or dry etching process. Because nitride sidewall spacers 110a are surrounded by ILD layer 112a of oxide material, the etching process may remove only nitride hard mask 106a and the top portion of nitride sidewall spacers 110a and therefore create an opening 211 that is surrounded directly by ILD layer 112a. The opening 211 also causes underneath dummy gate 104a to be exposed, and causes the remaining portion of dielectric layer 111b to become sidewall spacers 110b that are only next to the sidewalls of dummy gate 104a.

In one embodiment, wherein nitride hard mask 106a and nitride sidewall spacers 110a are of substantially same nitride material and thus are removed or etched away at a substantially same rate, dummy gate 104a and sidewall spacers 110b may have a coplanar top surface 202. In the meantime, ILD layer 112a may stay substantially un-etched due to etch selectivity. The removal of hard mask 106a and portion of spacers 110a creates opening 211, or a recessed area, within ILD layer 112a. As being discussed above with reference to FIG. 13, a top portion of ILD layer 112a may be made of re-filled HDP oxide to enhance etch-selectivity relative to nitride etching.

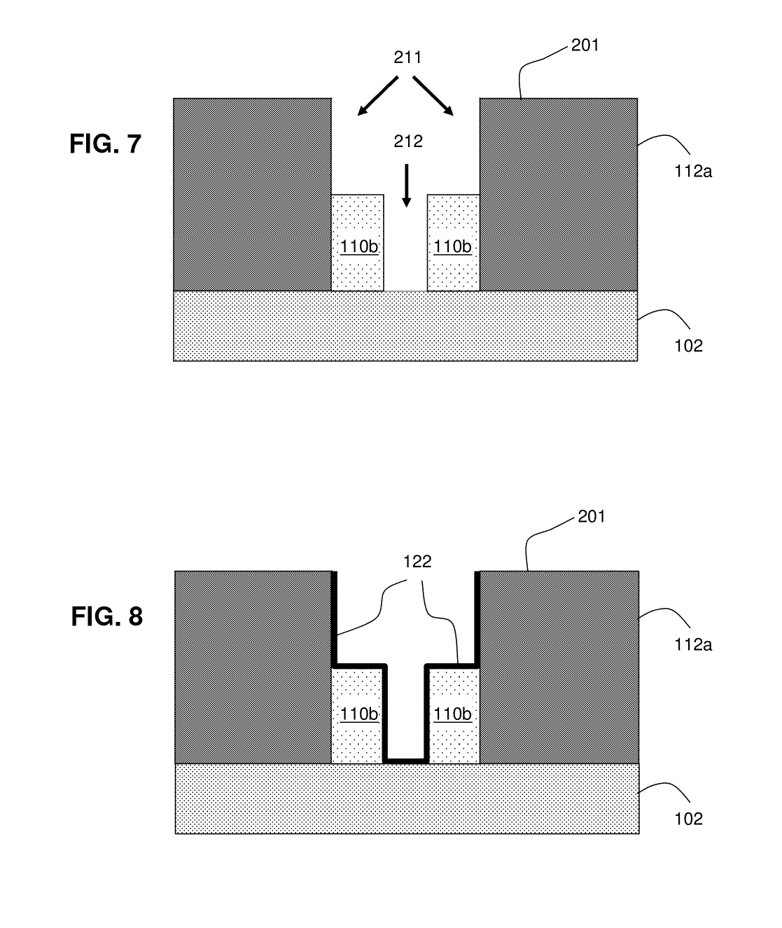

FIG. 7 is a demonstrative illustration of a method of forming a dielectric cap layer on a gate for borderless contacts of transistors according to an embodiment of present invention, following the step of FIG. 6. More specifically, after dummy gate 104a is exposed by the creation of opening 211 which is wider than the width of dummy gate 104a, dummy gate 104a may be selectively removed to create a recess or opening 212 that is directly surrounded by the remaining portion of dielectric layer 111b which are now sidewall spacers 110b. For example, dummy gate 104a may be made of poly-silicon, and poly-silicon may be selectively removed or etched away relative to nitride sidewall spacers 110b as well as oxide ILD layer 112a. The removal of dummy gate 104a may create recess or opening 212, which is narrower than that of opening 211 as being demonstratively illustrated in FIG. 7. Opening or recess 212 may subsequently be filled up with work-function metal and gap-filling metal to form a replacement metal gate.

FIG. 8 is a demonstrative illustration of a method of forming a dielectric cap layer on a gate for borderless contacts of transistors according to an embodiment of present invention, following the step of FIG. 7. More specifically, in forming a replacement gate such as a replacement metal gate, a high dielectric constant (high-k) dielectric liner 122 (such as HfOx, ZrOx, etc.) may first be deposited in recesses 211 and 212 created in previous steps. As being illustrated in FIG. 8, dielectric liner 122 may cover an exposed top surface of active layer 102, sidewalls and top surfaces of spacers 110b, and sidewalls of ILD layer 112a. In other words, dielectric liner 122 covers internal surfaces of opening 211 and 212. Dielectric liner 122 may be formed through a deposition process or other suitable existing or future developed processes.

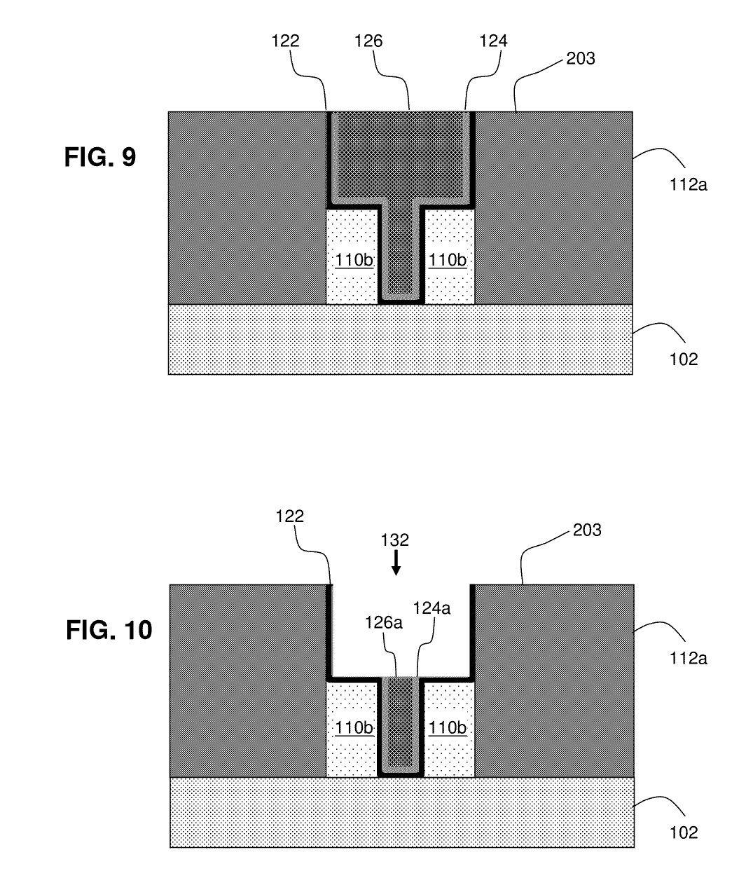

FIG. 9 is a demonstrative illustration of a method of forming a dielectric cap layer on a gate for borderless contacts of transistors according to an embodiment of present invention, following the step of FIG. 8. With recesses 211 and 212 being covered by high-k dielectric liner 122, a work-function metal layer 124 may next be formed on top of dielectric liner 122, as being demonstratively illustrated in FIG. 9. Material of work-function layer 124 may include, for example, TiN, TiAl, TiAlN, Ti-carbide, Ta-carbide, Ru, and/or W, to list a few. However, embodiment of present invention is not limited in this aspect and other material may be used as well. In some embodiment, multiple layers of different work-function metals may be applied in order to tune or modulate work-function of the transistor.

On top of work-function metal layer 124, gap-filling conductive gate material may be deposited to fill up the remaining region of recessed area 212 between spacers 110b. For example, in a replacement metal gate, aluminum (Al) may preferably be used as gap-filling conductive material 126 to fill recessed area 212 although other metals such as tungsten (W) may be used as well. Gap-filling material 126 may also fill any remaining areas of opening 211 above opening 212. As another example of non-metal gate, instead of work-function metal layer 124 and conductive gate material 126, material such as epitaxial silicon and/or silicide may be formed in the remaining recessed area 212, for example, by depositing, or performing epitaxial growth of, silicon in the recess and then performing silicidation, at proper temperature, of the deposited silicon covered by suitable metal.

The deposition and/or formation of dielectric liner 122, work-function metal layer 124, and gap-filling conductive material 126 may have the top surface 201 of ILD layer 112a being covered by these materials as well, which may be removed through a CMP process. The CMP process may create a top surface 203 that is co-planar with that of gap-filling conductive material 126 and ILD layer 112a.

FIG. 10 is a demonstrative illustration of a method of forming a dielectric cap layer on a gate for borderless contacts of transistors according to an embodiment of present invention, following the step of FIG. 9. During this process, gap-filling conductive material 126 within the opening 211 may be removed through a selective etching process. More specifically, conductive material 126 in the region of recess 211 above previous region of dummy gate 104a may be removed, in a selective etching process using dielectric liner 122 as end point for the etching process. The selective etching process creates a new opening or recessed area 132 in the previous recessed region 211, and exposes the remaining portion of gap-filling conductive material 126, denoted now as 126a, and remaining portion of work-function metal 124, denoted now as 124a, that are surrounded by sidewall spacers 110b. Gap-filling conductive material 126a and work-function metal 124a form a replacement metal gate.

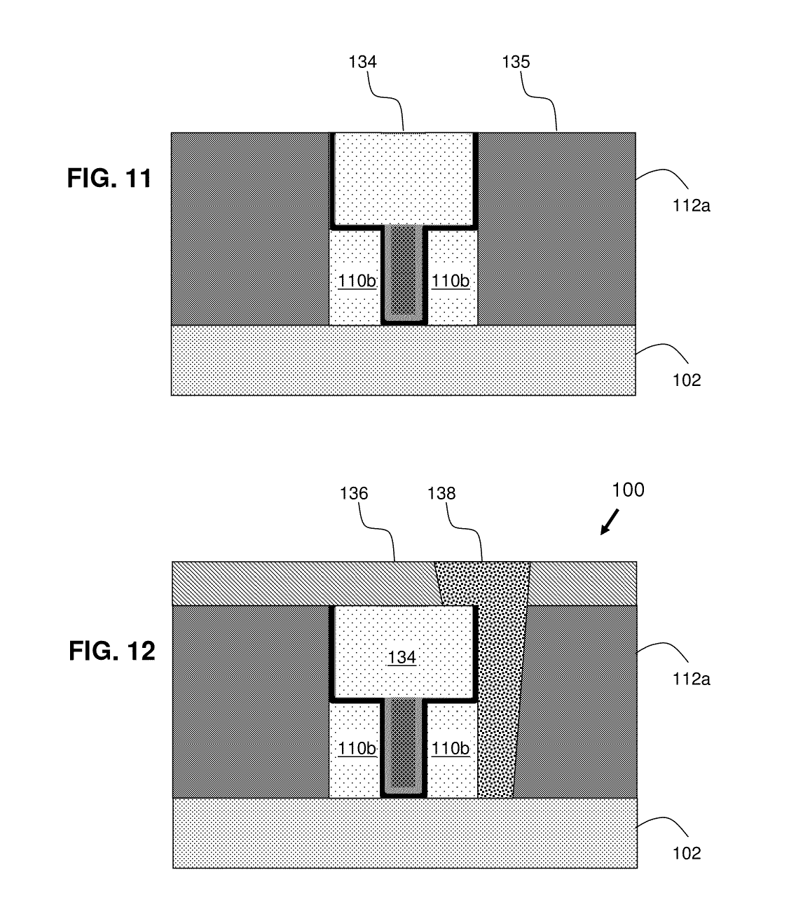

Once work-function metal 124 and conductive gate material 126 in the region of recess 211 are removed, the new recessed area 132 is then transformed into a dielectric cap. The transformation may be made by filling the recessed area 132 with dielectric isolating material to form a dielectric cap layer 134, as being demonstratively illustrated in FIG. 11, which covers replacement metal gate 126a and is above sidewall spacers 110b as well. The dielectric cap or dielectric cap layer 134 may be formed through a regular deposition process or other existing or future developed processes. After the deposition of dielectric layer 134, a CMP process may be applied to remove any excess dielectric material that may be above ILD layer 112a to create a planar top surface 135, preparing for a follow-up step of forming self-aligned contact to source/drain of the transistor 100.

According to one embodiment of present invention, conductive contact, and in particular self-aligned contact (SAC), to source/drain of transistor 100 may be formed with the help of dielectric cap 134 covering replacement metal gate 126a. As being demonstratively illustrated in FIG. 12 as well as in FIG. 14, self-aligned contact 138 may be formed through a regular photo-lithographic pattern and etching process. FIG. 14 illustrates a situation when the structure illustrated in FIG. 13 instead of the structure illustrated in FIG. 4 is used. For example, a photo-resist layer may first be applied on top of ILD layer 112a and dielectric cap 134, through a spin-on process for example. A pattern of conductive contact may then be formed in the photo-resist layer. The conductive contact pattern may be aligned to or even slightly overlap with dielectric cap layer 134. Dielectric material of ILD layer 112a defined by the contact pattern may be selectively removed or etched away to create a via hole next to dielectric cap layer 134 and sidewall spacers 110b. Because of the difference in etch selectivity between ILD layer 112a and sidewall spacers 110b as well as dielectric cap layer 134, the via hole may be created to be self-aligned to sidewall spacers 110b and dielectric cap layer 134. Conductive materials such as metal may subsequently be filled into the via hole to form conductive contact 138.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the spirit of the invention.

1. A method comprising:
forming a sacrificial gate stack having a sacrificial gate on top of a channel region of a transistor and a hard mask on top of said sacrificial gate, said hard mask having an upper portion and a lower portion and said upper portion being materially different from said lower portion;
forming spacers adjacent to sidewalls of said sacrificial gate stack, said spacers being embedded in a layer of dielectric material;
applying a chemical-mechanic-polishing (CMP) process to remove said upper portion of said hard mask and corresponding upper portions of said spacers and said layer of dielectric material thereby forming a sacrificial gate structure embedded in a lower portion of said layer of dielectric material, wherein said lower portion of said layer of dielectric material being a first dielectric layer and said sacrificial gate structure comprising said sacrificial gate; said lower portion of said hard mask; and lower portions of said spacers, wherein said lower portion of said hard mask and said lower portions of said spacers collectively forming a second dielectric layer surrounding a top and sidewalls of said sacrificial gate;
removing a portion of said second dielectric layer that is above a top level of said sacrificial gate to create a first opening surrounded directly by said first dielectric layer;
removing said sacrificial gate exposed by said removing of said portion of said second dielectric layer to create a second opening surrounded by a remaining portion of said second dielectric layer, said second opening having a narrower width than that of said first opening;
filling said second opening with one or more conductive materials to form a gate of said transistor; and
forming a dielectric cap of said gate of said transistor inside said first opening.

2. The method of claim 1, further comprising:
creating a third opening in said first dielectric layer, said third opening being self-aligned to said dielectric cap and said remaining portion of said second dielectric layer underneath said dielectric cap surrounding said gate of said transistor; and
filling said third opening with a conductive material to form a contact to a source/drain of said transistor.

3. The method of claim 2, wherein creating said third opening comprises applying a selective etching process to etch said first dielectric layer, said etching process being selective to said dielectric cap and said remaining portion of said second dielectric layer underneath thereof.

4. The method of claim 3, wherein said dielectric cap and said second dielectric layer are of nitride material and said first dielectric layer is of oxide material.

5. The method of claim 1, wherein said first dielectric layer comprises a lower portion of flowable oxide and an upper portion of high density plasma deposited oxide, and wherein said upper portion of said hard mask being oxide material and said lower portion of said hard mask being nitride material.

6. (canceled)

7. (canceled)

8. (canceled)

9. (canceled)

10. The method of claim 1, wherein said one or more conductive materials comprise a work-function metal and a gap-filling metal of aluminum, and wherein filling said second opening with said one or more conductive materials comprises:
depositing said work-function metal in at least said second opening;
depositing said gap-filling metal of aluminum on top of said work-function metal and inside said second opening; and
substantially removing said work-function metal and said gap-filling metal of aluminum that are deposited in the first opening through a selective etching process by applying a dielectric liner underneath said work-function metal as an etch-stop layer,
wherein said dielectric liner is deposited prior to depositing said work-function metal.

11. (canceled)

12. A method comprising:
forming a sacrificial gate structure embedded in a first dielectric layer, said sacrificial gate structure comprising a sacrificial gate and a second dielectric layer wherein said second dielectric layer covering a top and sidewalls of said sacrificial gate, said sacrificial gate structure having a width at a top thereof that is substantially same as a width at a bottom of said sacrificial gate structure, and said sacrificial gate having a width between 35% and 65% of said width at said bottom of said sacrificial gate structure;
removing at least a portion of said second dielectric layer that is above said sacrificial gate to create a first opening to expose said sacrificial gate;
removing said exposed sacrificial gate to create a second opening surrounded by a remaining portion of said second dielectric layer, said second opening having a width narrower than that of said first opening;
filling said second opening with one or more conductive materials to form a gate of a transistor; and
filling said first opening with a layer of dielectric material to form a dielectric cap of said gate of said transistor.

13. The method of claim 12, wherein removing said at least a portion of said second dielectric layer comprises removing a part of said second dielectric layer that is above a top level of said sacrificial gate such that said first opening is directly surrounded by said first dielectric layer.

14. The method of claim 13, further comprising:
creating a third opening in said first dielectric layer, said third opening being self-aligned to said dielectric cap and said remaining portion of said second dielectric layer, said remaining portion being underneath said dielectric cap and surrounding sidewalls of said gate of said transistor; and
filling said third opening with a conductive material to form a contact to a source/drain of said transistor.

15. The method of claim 14, wherein creating said third opening comprises applying a selective etching process to etch said first dielectric layer, said etching process being selective to said dielectric cap and said remaining portion of said second dielectric layer.

16. The method of claim 15, wherein said dielectric cap and said remaining portion of said second dielectric layer are of nitride material and said first dielectric layer is of oxide material.

17. The method of claim 12, wherein said first dielectric layer consisting of a lower portion and an upper portion, said lower portion being a flowable oxide and said upper portion being an oxide deposited through a high density plasma process.

18. The method of claim 12, wherein forming said sacrificial gate structure comprises:
forming a hard mask on top of a layer of dummy gate material, said hard mask having a lower portion of nitride and an upper portion of oxide;
etching said layer of dummy gate material into said dummy gate using said hard mask as a pattern of said dummy gate;
forming a set of spacers at sidewalls of said hard mask and sidewalls of said dummy gate;
forming said first dielectric layer surrounding said set of spacers; and
applying a chemical-mechanic-polishing (CMP) process to remove said upper portion of oxide of said hard mask and top portions of said set of spacers.

19. The method of claim 18, wherein said set of spacers are of nitride and wherein remaining portions of said set of spacers, together with said lower portion of said hard mask of nitride, form said second dielectric layer.

20. The method of claim 19, wherein said nitride of said set of spacers is materially substantially same as said nitride of said lower portion of said hard mask.

21. The method of claim 12, wherein said one or more conductive materials comprise a work-function metal and a gap-filling metal of aluminum, and wherein filling said second opening with said one or more conductive materials comprises:
depositing a dielectric liner covering bottoms and sidewalls of said first and said second openings respectively;
depositing a layer of said work-function metal covering said dielectric liner;
depositing said gap-filling metal of aluminum on top of said layer of said work-function metal; and
substantially removing said work-function metal and said gap-filling metal of aluminum that are deposited in the first opening through a selective etching process by applying said dielectric liner underneath said work-function metal as an etch-stop layer.

22. The method of claim 12, wherein said transistor is a fin-type field-effect-transistor (fin-FET) and said gate is formed over a channel region of said fin-FET.

23. A method comprising:
forming a sacrificial gate structure and embedding said sacrificial gate structure in a first dielectric layer, wherein said sacrificial gate structure includes a sacrificial gate and a second dielectric layer, said second dielectric layer has a first portion and a second portion with said first portion being above a top level of said sacrificial gate and said second portion being adjacent to sidewalls of said sacrificial gate, respectively, said sacrificial gate structure having a first width at a top thereof and a second width at a bottom thereof and said first and second widths being less than 5% in difference, and said sacrificial gate having a width less than 50% of said second width at said bottom of said sacrificial gate structure;
removing said first portion of said second dielectric layer to expose said sacrificial gate by creating a first opening that is wider than a width of said sacrificial gate;
removing said exposed sacrificial gate to create a second opening surrounded by said second portion of said second dielectric layer;
filling said second opening with one or more conductive materials to form a gate of a transistor; and
filling said first opening with a layer of dielectric material to form a dielectric cap of said gate of said transistor.

24. The method of claim 23, further comprising:
creating a third opening in said first dielectric layer, said third opening being self-aligned to said dielectric cap and said second portion of said second dielectric layer, said second portion being underneath said dielectric cap and surrounding sidewalls of said gate of said transistor; and
filling said third opening with a conductive material to form a contact to a source/drain of said transistor.

25. The method of claim 24, wherein creating said third opening comprises applying a selective etching process to etch said first dielectric layer, said etching process being selective to said dielectric cap and said second portion of said second dielectric layer.

26. The method of claim 25, wherein said dielectric cap and said second portion of said second dielectric layer are of nitride material and said first dielectric layer is of oxide material.
